(19) United States
(12) Patent Application Publication
(10) Pub. No.: US 2015/0000864 A1
(43) Pub. Date: Jan. 1, 2015

(54) COOLING SYSTEM OF MULTIPLE HEAT GENERATING DEVICES

(71) Applicant: FUJITSU LIMITED, Kawasaki-shi (JP)

(72) Inventor: Shinichi KOBAYASHI, Kawasaki (JP)

(73) Assignee: FUJITSU LIMITED, Kawasaki-shi (JP)

(21) Appl. No.: 14/489,562

(22) Filed: Sep. 18, 2014

Related U.S. Application Data
(63) Continuation of application No. PCT/JP2012/057080, filed on Mar. 19, 2012.

(51) Int. Cl. H05K 7/20

(52) U.S. Cl. CPC H05K 7/20454
USPC 165/46

(57) ABSTRACT

A cooling system of multiple heat generating devices which can be inserted into and detached from an electronic apparatus, wherein the electronic apparatus is provided with rigid frames for cooling the heat generating devices, flexible bags for circulating cooling medium attached to the facing surfaces of the rigid frames, and pressing sheets provided in the front-back direction of the rigid frames over the flexible bags whose back end sides are fixed to the rigid frames, the intermediate parts are made to contact the flexible bags, and the other ends are attached to shafts which can roll up the pressing sheets according to the insertion depth of the heat generating devices into the rigid frames. The shaft drive mechanisms provided at insertion ends of the heat generating devices make the shafts rotate to roll up or unroll the pressing sheets when it is inserted into or withdrawn from the electronic apparatus.

### CROSS-REFERENCE TO RELATED APPLICATION

This application is a continuation application based upon and claiming priority of PCT Application No. PCT/JP2012/057080, filed on Mar. 19, 2012, the contents being incorporated herein by reference.

### FIELD

The embodiments which are disclosed here relate to a cooling system.

### BACKGROUND

In the past, as an electronic apparatus, there has been known a large capacity storage apparatus which houses a large number of storage devices such as hard disk drives. Such a large capacity storage apparatus, as in the related art which is illustrated in FIG. 1A, FIG. 1B, and FIG. 1C, is comprised of a large capacity storage apparatus 1 with a housing at one end of which a large number of hard disk drives 2 are loaded aligned. At the center part of the housing of the large capacity storage apparatus 1, there are control parts 3 and power parts 4. At the other end of the housing of the large capacity storage apparatus 1, blower fans 5 for air cooling use are provided. The blower fans 5 are of types which suck in the cooling air from the sides where the hard disk drives 2 are loaded from the top and discharge it from their backs. Between the hard disk drives 2 and the control parts 3 and power parts 4, a partition wall constituted by a “back plane” 6 is provided. Further, the control parts 3 and power parts 4 are provided in two systems forming a redundant configuration.

In such a structure of a large capacity storage apparatus 1, the air flow which is required for cooling the hard disk drives 2 is large. The volume of the air which was blown by the blower fans 5 was large and the fan noise was great. On top of that, the power consumed by the blower fans 5 was large. Therefore, it has been proposed to cool electronic devices which generate heat by a cooling system of a water cooling type rather than an air cooling type (see Japanese Laid-Open Patent Publication No. 5-267875). In the water cooling system of a printed circuit board which is described in Japanese Laid-Open Patent Publication No. 5-267875, mounting hardware is used to detachably attach a water cooling head to a printed circuit board. Further, the water cooling head is made a bag shape which has enough flexibility to deform to match the outer shapes of the components mounted on the printed circuit board and is structured so that a coolant is circulated inside. Furthermore, the water cooling head is connected by piping to a thermo transfer unit. Cooling water which circulated through the water cooling head is cooled by the thermo transfer unit and returned to the water cooling head.

However, the water cooling system of the printed circuit board which is described in Japanese Laid-Open Patent Publication No. 5-267875 uses mounting hardware which is screwed into a single printed circuit board so as to attach the cooling head above the printed circuit board and cannot be applied to the large capacity storage apparatus which stores a large number of storage devices which is illustrated in FIGS. 1A to 1C. That is, the water cooling system of the printed circuit board which is described in Japanese Laid-Open Patent Publication No. 5-267875 moves the cooling head in the vertical direction with respect to the printed circuit board and cannot be applied to a large capacity storage apparatus which makes printed circuit boards move in a parallel direction with respect to a fixed cooling head.

### SUMMARY

In one aspect, the present application provides a cooling system of multiple heat generating devices which can be applied to a large capacity storage apparatus which inserts and withdraws a plurality of printed circuit boards by making them move in a parallel direction with respect to a fixed cooling head.

Further, in another aspect, the present application provides a cooling system of multiple heat generating devices which enables active exchange wherein the cooling system functions for other printed circuit boards even if one of a plurality of printed circuit boards is exchanged.

For this reason, the cooling system of multiple heat generating devices of the present application provides a cooling system of multiple heat generating devices which can be inserted into and detached from an electronic apparatus, characterized by being provided with rigid body type frames which are provided at the electronic apparatus to be positioned at the two side surfaces of the heat generating devices, flexible bag shaped members which are attached to the surfaces of the rigid body type frames which face side surfaces of the heat generating devices and inside of which a cooling medium circulates, pressing sheets which have first ends which are fastened to the back end sides of the rigid body type frames, the side where the heat generating devices are inserted in the electronic apparatus being defined as the front sides, which have intermediate parts which cover the bag shaped members, which have other ends which are attached to shafts which can move over the rigid body type frames in the front-back direction, and which are wound around the shafts due to movement of the shafts, and shaft drive mechanisms which are provided at front end parts of the heat generating devices and which makes the shafts rotate at the time of insertion or detachment of the heat generating devices.

In this case, each shaft may be provided with a windup part of a pressing sheet and roller parts which are provided with a larger diameter than the windup part and is driven by a shaft drive mechanism to rotate and move over a rigid body type frame, and the shaft drive mechanism may be provided inside a recessed part which is provided at a heat generating device and may be formed provided with a first roller which abuts against the roller parts to make them rotate, a second roller which is provided separated from the first roller by a distance of at least the diameter of the roller parts and which has a larger diameter than the first roller, and an extension-retraction mechanism which makes the first and second rollers extend from and retract into the heat generating device.

Further, the extension-retraction mechanism may be configured from an elevator plate to which shafts of the first and second rollers are attached and a compression spring which is provided between the elevator plate and recessed part, the diameter of the second roller may be made equal to the diameter of the roller parts, the roller parts may be made to rotate by the first roller with a diameter smaller than the second roller along with the heat generating device being inserted into the electronic apparatus, and a pressing sheet may be made to be wound up by the windup part while pressing against a bag shaped member.

Furthermore, the two end parts of the rigid body type frame in a direction vertical to the front-back direction are formed with grooves which extend in the front-back direction. In the grooves, sliders which slide in the front-back direction along the grooves are inserted. The two end parts of the shaft are supported at the sliders to be able to rotate. The positions of the back end parts of the grooves may be made positions whereby the heat generating device is left with a margin for further insertion in the state where the sliders move to the back end parts of the grooves. Further, the total length of the heat generating device may be made a length whereby insertion into the electronic apparatus ends when insertion of the heat generating device in the electronic apparatus after the end of movement of the shaft causes the shaft drive mechanism to sink into the recessed part and the first roller rides over the roller parts.

### BRIEF DESCRIPTION OF DRAWINGS

FIG. 1A is a plan view of a cooling system of hard disks of the related art.

FIG. 1B is a back view of the cooling system of hard disks which is illustrated in FIG. 1A.

FIG. 1C is a side view of the cooling system of a hard disk which is illustrated in FIG. 1A.

FIG. 2A is a plan view of a large capacity storage apparatus which is provided with cooling systems of multiple heat generating devices of the present application and enables the insertion and ejection of hard disk drives.

FIG. 2B is a back view of the large capacity storage apparatus which is illustrated in FIG. 2A.

FIG. 2C is a side view of the large capacity storage apparatus which is illustrated in FIG. 2A.

FIG. 3 is a block circuit diagram which illustrates cooling systems of multiple heat generating devices of the present application which are illustrated in FIG. 2A to FIG. 2C.

FIG. 4A is plan view of a cooling plate which is used for the cooling system of multiple heat generating devices of the present application.

FIG. 4B is a side view of the cooling plate which is illustrated in FIG. 4A.

FIG. 4C is a front view of the cooling plate which is illustrated in FIG. 4A.

FIG. 4D is a perspective view which illustrates the configuration of an internal channel of the cooling plate which is illustrated in FIG. 3 and connection with a manifold.

FIG. 5 is a perspective view of a cooling plate of one embodiment of the present application.

FIG. 6A is a side view of the cooling plate which is illustrated in FIG. 5.

FIG. 6B is a side view of a cooling plate which illustrates the state where a pressing sheet is wound up from the state which is illustrated in FIG. 6A.

FIG. 6C is a side view of a cooling plate which illustrates the state where the pressing sheet is completely wound up from the state which is illustrated in FIG. 6B.

FIG. 7A is a partial front view which illustrates the configuration of a pressing sheet drive mechanism which is provided at a heat generating device of the cooling system of multiple heat generating devices of the present application.

FIG. 7B is an assembled perspective view of a pressing sheet drive mechanism which illustrates the configuration of the pressing sheet drive mechanism which is illustrated in FIG. 7A.

FIG. 7C is a partial front view which illustrates a retracting operation of the pressing sheet drive mechanism which is illustrated in FIG. 7A.

FIG. 8A to FIG. 8E are explanatory views which explain in stages the operation of insertion of a heat generating device in the cooling system of multiple heat generating devices of the present application.

FIG. 9A to FIG. 9E are explanatory views which explain in stages the operation of withdrawal of a heat generating device from the cooling system of multiple heat generating devices of the present application.

FIG. 10A is a partially enlarged view of a part A which is illustrated in FIG. 8B.

FIG. 10B is a partially enlarged view of a part B which is illustrated in FIG. 9B.

### DESCRIPTION OF EMBODIMENTS

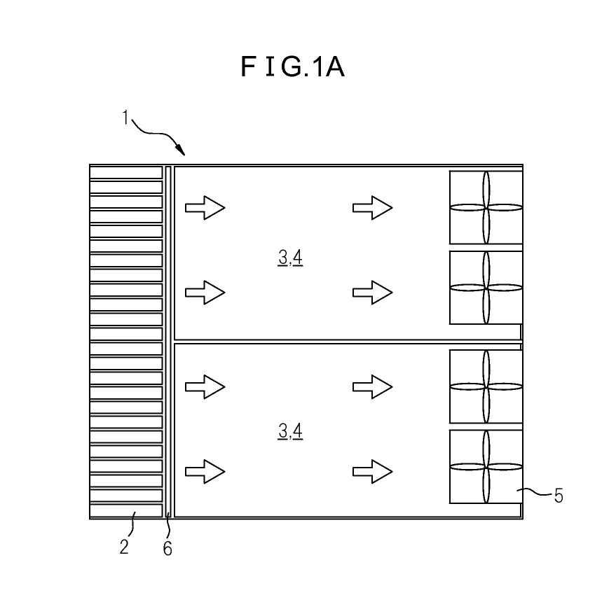

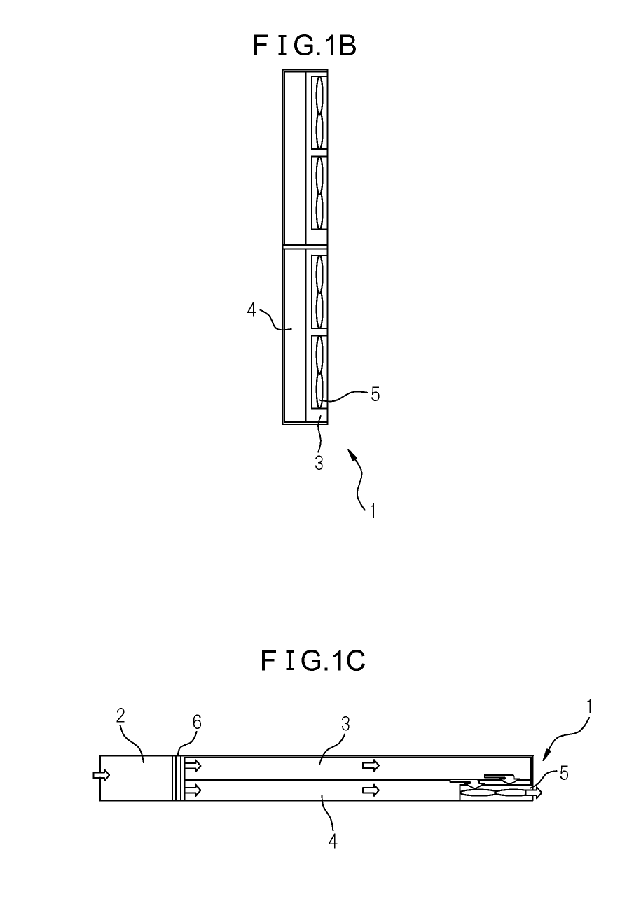

Below, figures will be used to explain preferred embodiments of the present application. Note that, as the electronic apparatus, a large capacity storage apparatus 1 will be explained. Component parts the same as the one which was explained from FIG. 1A to FIG. 1C are assigned the same reference numerals. Note that, in the embodiments which are explained below, a large capacity storage apparatus will be explained as the electronic apparatus and hard disk drives will be explained as the heat generating devices, but the electronic apparatus and the heat generating devices are not limited to these. The electronic apparatus may be any apparatus which is provided with heat generating members inside of it. Further, the side of insertion of the hard disk drives to the large capacity storage apparatus will be explained as the front side.

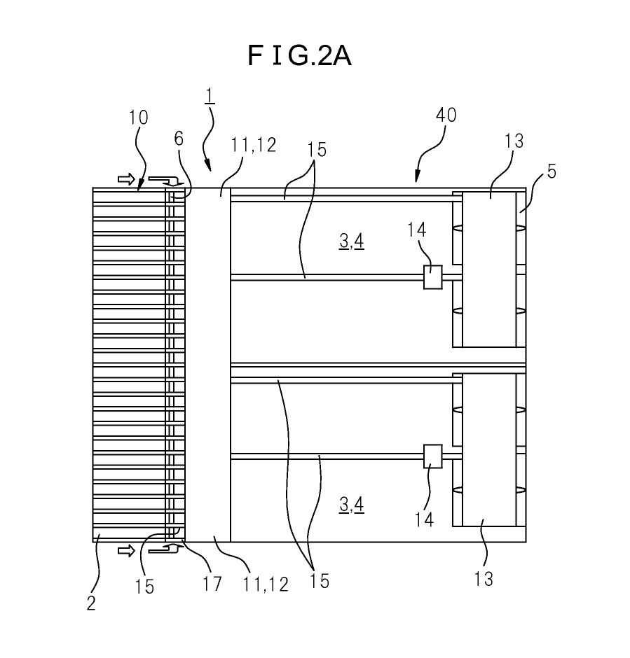

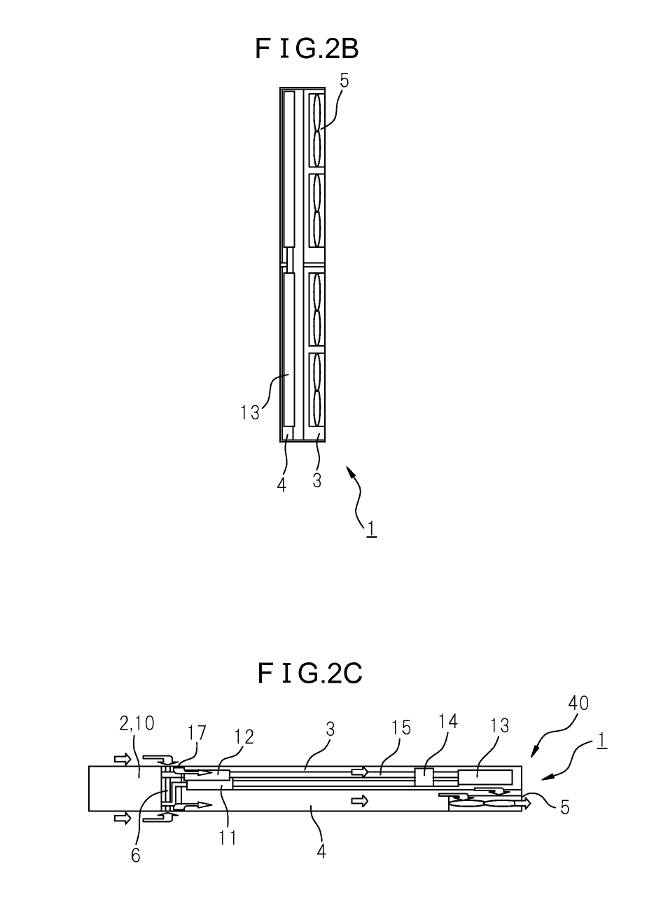

FIG. 2A is a plan view of one embodiment of a large capacity storage apparatus 1 which is provided with cooling systems 40 of multiple heat generating devices of the present application. The large capacity storage apparatus 1 houses a plurality of hard disk drives 2 able to be inserted into and detached from a front end part. FIG. 2B is a back view of the large capacity storage apparatus 1 which is illustrated in FIG. 2A, while FIG. 2C is a side view of the large capacity storage apparatus 1 which is illustrated in FIG. 2A. At the part of the housing of the large capacity storage apparatus 1 at the side behind a back plane 6, there are control parts 3 and power parts 4. At the back end part of the housing of the large capacity storage apparatus 1, blower fans 5 are provided for air cooling. These points are the same as the large capacity storage apparatus 1 which was explained from FIG. 1A to FIG. 1C. The large capacity storage apparatus 1 of this embodiment is provided with two systems of control parts 3 and power parts 4 for a redundant configuration. The cooling air is sucked in from an intake part 17 to the inside of the housing of the large capacity storage apparatus 1.

The point where the large capacity storage apparatus 1 of the present application differs from the large capacity storage apparatus 1 which was explained from FIG. 1A to FIG. 1C is the point that two cooling system 40 of multiple heat generating devices are provided for cooling the hard disk drives 2. The cooling paths of the two cooling systems 40 of multiple heat generating devices are provided with cooling plates 10 which are inserted in the clearances between the hard disk drives 2, first and second manifolds 11 and 12, heat exchangers 13, pumps 14, and piping 15 which connects these and moves a cooling medium. The first manifold 11 is connected by the piping 15 to the cooling plates 10, gathers cooling medium after heat exchange from a large number of cooling plates 10, and sends the result by piping 15 to the heat exchangers 13. The cooling medium which is cooled by the heat exchangers 13 is sent by the pumps 14 to the second manifolds 12 where it is dispersed to the cooling plates 10.

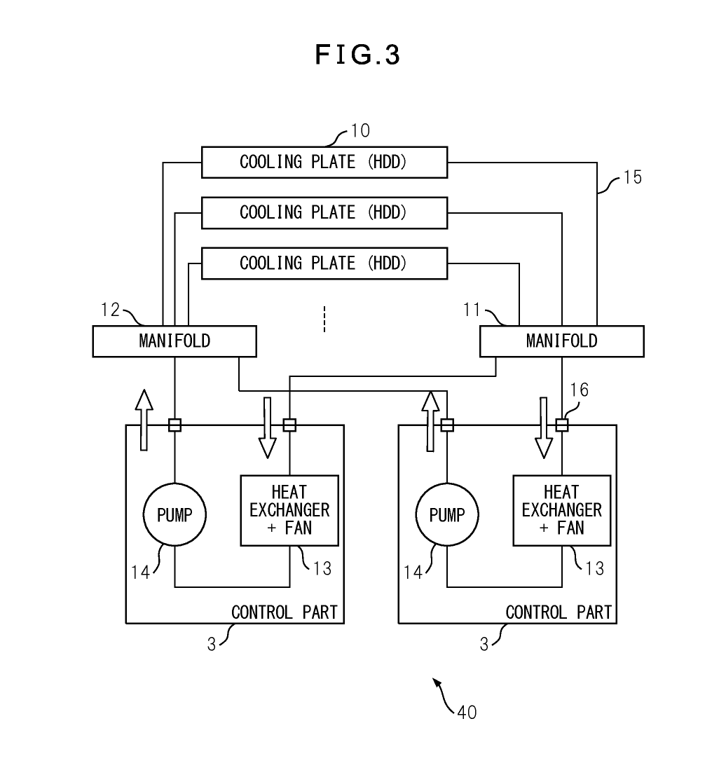

FIG. 3 is a block circuit diagram which illustrates the structure of one embodiment of the cooling systems of multiple heat generating devices of the present application which are illustrated from FIG. 2A to FIG. 2C. As explained above, a large number of cooling plates 10 are connected by the piping 15 to the first and second manifolds 11 and 12. In this embodiment, heat exchangers 13 and pumps 14 which are connected to heat exchangers 13 are placed at the two control parts 3. The output of the first manifold 11 is connected through connectors 16 to the heat exchangers 13 which are at the control parts 3, while the outputs of the pumps 14 are connected through the connectors 16 to the inlets of the first and second manifolds 11 and 12. Therefore, in this embodiment, when replacing heat exchangers 13 and pumps 14, they are detached by the connectors 16 and are exchanged for the individual control parts 3. Similarly, when replacing the control parts 3 as well, the heat exchangers 13 and pumps 14 are exchanged.

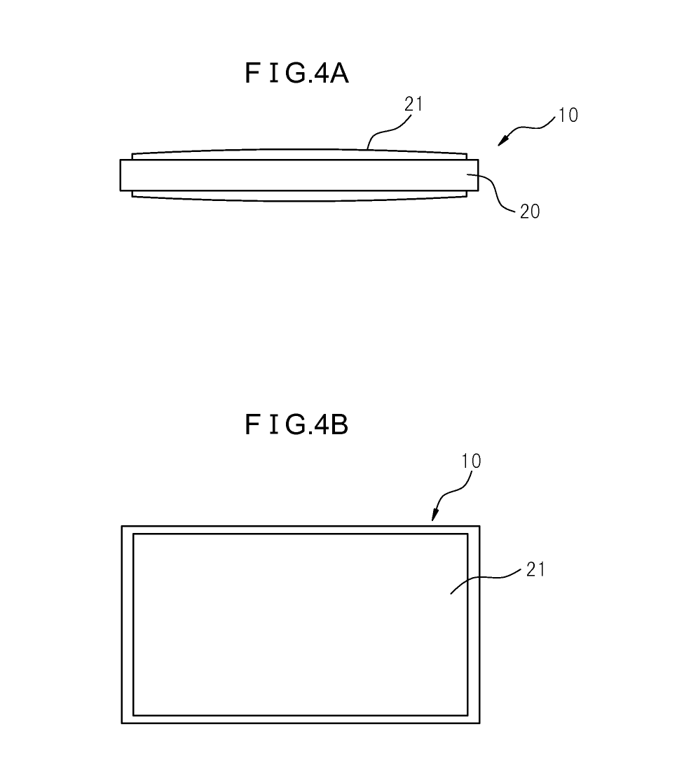

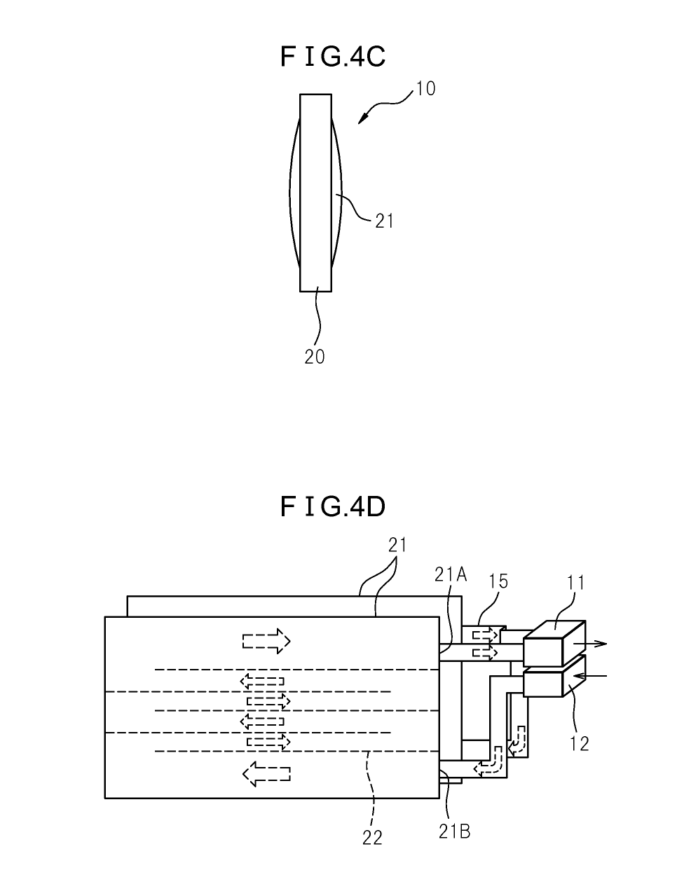

FIG. 4A to FIG. 4D explain the configuration of a cooling plate 10 which is used in the cooling system of multiple heat generating devices of the present application. The cooling plate 10 which is illustrated from FIG. 4A to FIG. 4C is provided with a rigid body type frame 20 and with bag shaped members which are attached to the two side surfaces of the rigid body type frame 20 facing the hard disk drives and which are provided with flexibility, that is, flexible bags 21. Hereinafter, the rigid body type frame 20 will be simply referred to as the “frame 20”. However, the frames 20 which are provided at the right-most end and left-most end of the hard disk loading parts are only provided with flexible bags 21 at single sides. The frames 20 can be formed by metal, while the flexible bags 21 can be formed by heat conductive plastic. The flexible bags 21 are shaped bulging out at the center parts when hard disk drives are not inserted, but if hard disk drives are inserted next to them, they deform to a uniform thickness. The side surface of each frame 20 is provided with an area which is equal to the side surface of a hard disk drive. The thickness of the frame 20 plus the flexible bags 21 (state of uniform thickness) is a thickness for insertion in a clearance between hard disk drives which are loaded in the electronic apparatus. The flexible bags 21 are filled with a cooling medium constituted by water or another liquid from not illustrated inlet parts. The cooling medium circulates through the insides of the flexible bags 21 and is discharged from not illustrated outlet parts.

FIG. 4D illustrates one embodiment of the internal configuration of a flexible bag 21 and an inlet part and outlet part of a cooling medium to and from the flexible bag 21. Inside of the flexible bag 21, partition walls 22 which alternately stick out from the end parts in the front-back direction of the flexible bag 21 are provided. The cooling medium follows the snaking path which is formed by the partition walls 22 and circulates inside the flexible bag 21 in a snaking manner. The outlet part 21A of the cooling medium of the flexible bag 21 is connected by piping 15 to the first manifold 11. Cooling medium from a plurality of flexible bags 21 is gathered at the first manifold 11 and heads toward the heat exchangers 13 which were explained in FIG. 3. Further, the inlet part 21B of the cooling medium of the flexible bag 21 is connected by piping 15 to the second manifold 12. The cooling medium which is cooled by the heat exchanger 13 is branched at the second manifold 12 and flows into the flexible bag 21 from the inlet part 21B of the cooling medium.

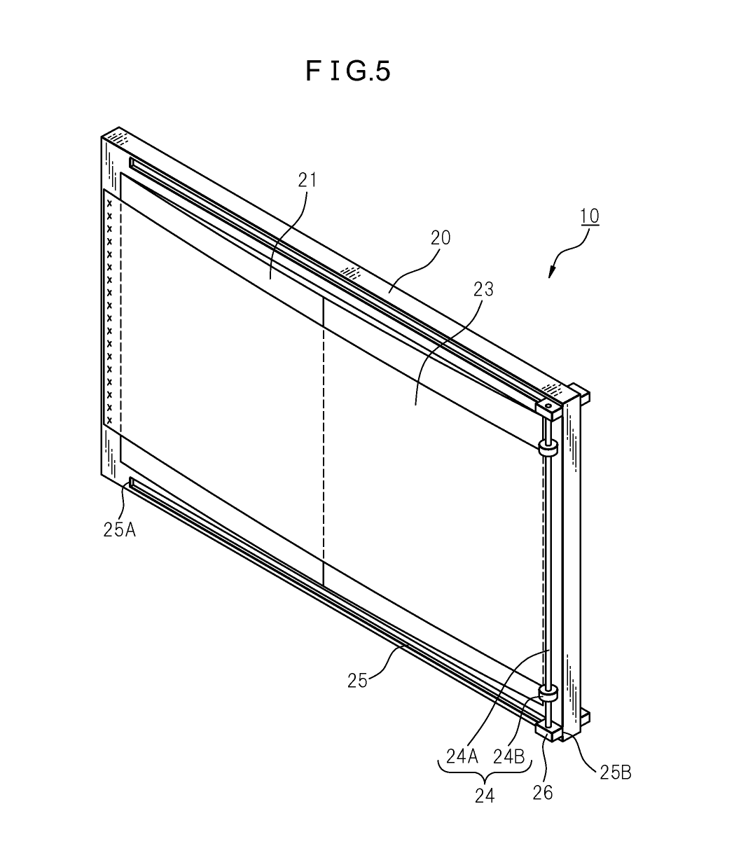

FIG. 5 illustrates a cooling plate 10 of one embodiment of the present application where a pressing sheet 23 is attached to a flexible bag 21 on the cooling plate 10 which was explained in FIG. 4A to FIG. 4D. Note that, illustration of the inlet part of the cooling medium to the flexible bag 21 and the outlet part of the cooling medium from the flexible bag 21 is omitted. If the frame 20 were only provided with the flexible bag 21, when a hard disk drive is inserted along the cooling plate 10, the cooling medium in the flexible bag 21 would be pushed by the front end part of the hard disk drive and move to the back end side of the flexible bag 21. This being so, the back end side of the flexible bag 21 would expand due to the moving cooling medium and the flexible bag 21 would be liable to burst.

Therefore, in the cooling plate 10 of the present invention, a pressing sheet 23 which makes the cooling medium move to the front end side of the flexible bag 21 when a hard disk drive is inserted is provided at the top side of the flexible bag 21. The width of the pressing sheet 23 in the direction vertical to the front-back direction of the cooling plate 10 (hereinafter referred to as “back vertical direction”) is shorter than the width of the flexible bag 21. Note that, to facilitate understanding, the flexible bag 21 which is illustrated in FIG. 5 is drawn so that the center part rises up linearly in the front-back direction.

One end of the pressing sheet 23 is fastened to a back end part of the frame 20, the other end is fastened to a windup part 24A of a shaft 24, and the intermediate part covers the flexible bag 21 and closely contacts the flexible bag 21. The shaft 24 is provided with a windup part 24A and two roller parts 24B with diameters larger than this. The distance between two roller parts 24B is slightly larger than the width of the pressing sheet 23. At the two end parts of the frame 20 in the vertical direction, grooves 25 are provided with extend in the front-back direction. In the grooves 25, sliders 26 are attached to be able to slide in the grooves 25.

Further, the two sliders 26 support the shaft 24 at the parts outsides from the roller parts 24B to be enable it to rotate. Therefore, the shaft 24 can rotate and move on the frame 20. The back end parts 25A of the grooves 25 are at the front side from the end part of the back end part side of the flexible bag 21, while the front end parts 25B of the grooves 25 are provided with not illustrated lock mechanisms which lock the sliders 26 at those positions. The pressing sheet 23, one end of which is fastened to the back end part of the frame 20 and the other end of which is fastened to the windup part 24A of the shaft 24, closely contacts the outside surface of the flexible bag 21 in the state where the sliders 26 are locked with the front end parts 25B of the grooves 25. Further, the locking of the sliders 26 by the front end partd 25B of the grooved 25 is of an extent whereby they are easily detached when a hard disk drive is inserted next to the cooling plate 10 and the shaft 24 moves to the back end part side.

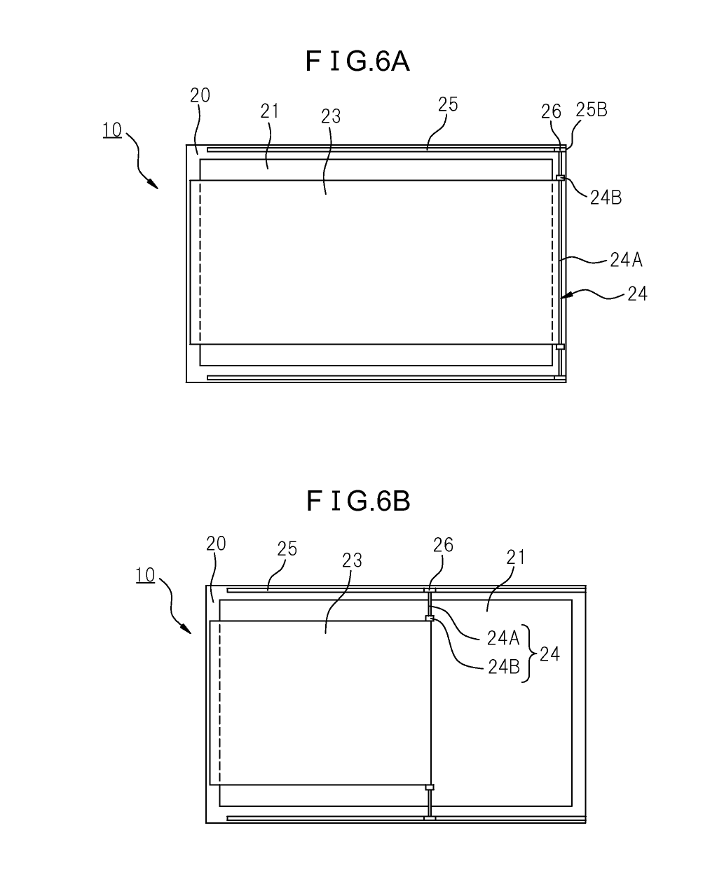

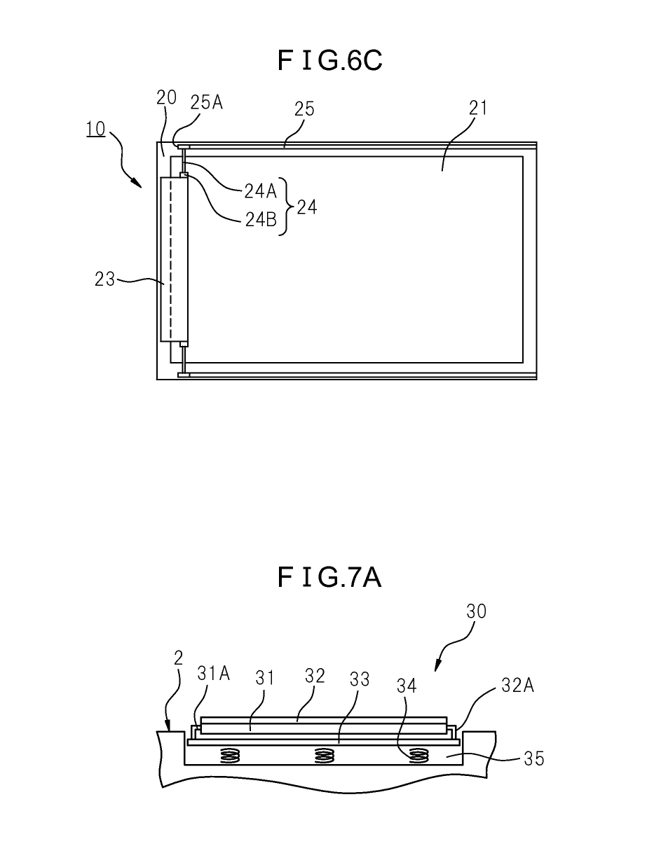

FIG. 6A is a view of the cooling plate 10 which is illustrated in FIG. 5 as seen from the side surface. In this state, the sliders 26 are engaged with the front end parts 25B of the grooves 25, while the pressing sheet 23 closely contacts the outside surface of the flexible bag 21. In this state, if a hard disk drive is inserted next to the cooling plate 10, as illustrated in FIG. 6B, the shaft 24 rotates while being pressed against by the hard disk drive and the pressing sheet 23 is wound up by the windup part 24A of the shaft 24. The mechanism by which the hard disk drive is used to drive the shaft 24 will be explained later. If the windup part 24A of the shaft 24 winds up the pressing sheet 23, the outside surface of the flexible bag 21 is pressed against planarly by the pressing sheet 23 and the cooling medium inside the flexible bag 21 smoothly moves from the back end part side to the front end part side. Accordingly, when a hard disk drive is inserted, the cooling medium in the flexible bag 21 will not concentrate at the back end part side. FIG. 6C illustrates the state where the sliders 26 reach the back end parts 25A of the grooves 25 and the pressing sheet 23 which is illustrated in FIG. 6B is completely wound up. In this state, the pressing sheet 23 does not act on the flexible bag 21.

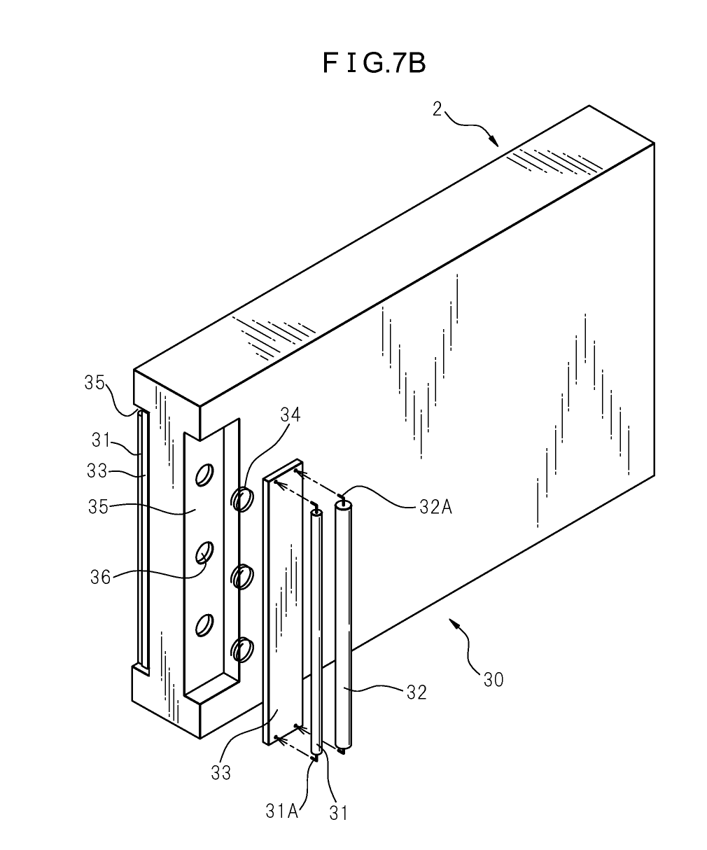

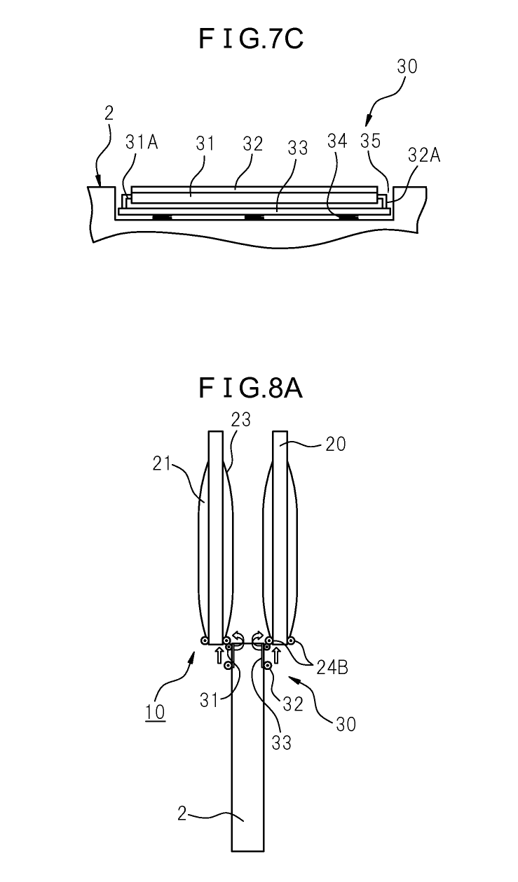

Here, the shaft drive mechanism 30 which is provided at the front end part of the hard disk drive which makes the shaft 24 move as illustrated from FIG. 6A to FIG. 6C will be explained using FIG. 7A to FIG. 7C. As illustrated in FIGS. 7A and 7B, the shaft drive mechanism 30 is attached to a recessed part 35 which is provided at a front end part of the hard disk drive 2. The shaft drive mechanism 30 is provided with a first roller 31, second roller 32, elevator plate 33, and springs 34. The elevator plate 33 and springs 34 form an extension-retraction mechanism of the first and second rollers 31 and 32. The diameter of the first roller 31 is smaller than the diameter of the second roller 32. A shaft 31A of the first roller 31 is attached to a front end side of the elevator plate 33. Further, the lengths of the first and second rollers 31 and 32 are longer than the distances of the two roller parts 24B at the shaft 24. Furthermore, a shaft 32A of the second roller 32 is attached to a back end side of the elevator plate 33, but the shaft 32A is attached to the elevator plate 33 with a space so that the roller parts 24B of the shaft 24 enter between the first and second rollers 31 and 32 which are attached to the elevator plate 33.

In this embodiment, at the bottom surface of the recessed part 35 which is provided at the front end part of the hard disk drive 2, there are spring holes 36. In the spring holes 36, the springs 34 are loaded. On top of these, the elevator plate 33 is fastened. The spring holes 36 need not necessarily be provided. Further, the number of springs 34 is not particularly limited. In the state where the shaft drive mechanism 30 is provided at the recessed part 35 which is provided at the front part of the hard disk drive 2, as illustrated in FIG. 7A, the first roller 31 and the second roller 32 stick out to the outside of the recessed part 35. Further, when the first roller 31 or the second roller 32 is subjected to external force directed to the bottom direction of the recessed part 35, the elevator plate 33 compresses the spring 34 and sinks into the recessed part 35 so that the second roller 32 is housed in the recessed part 35 as illustrated in FIG. 7C.

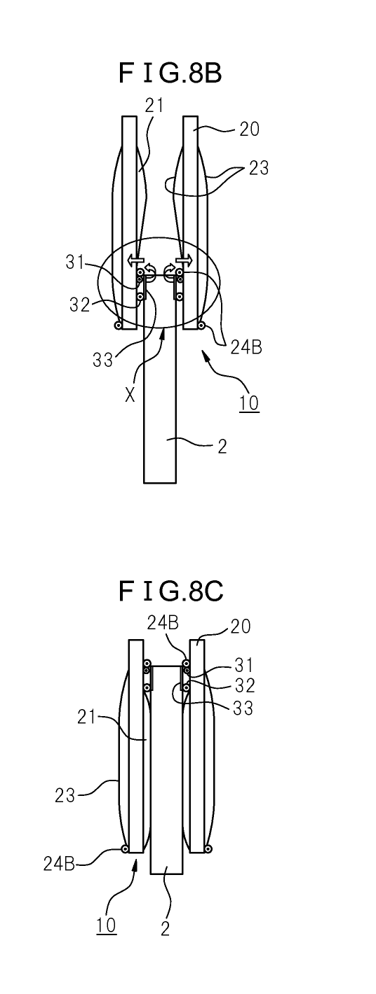

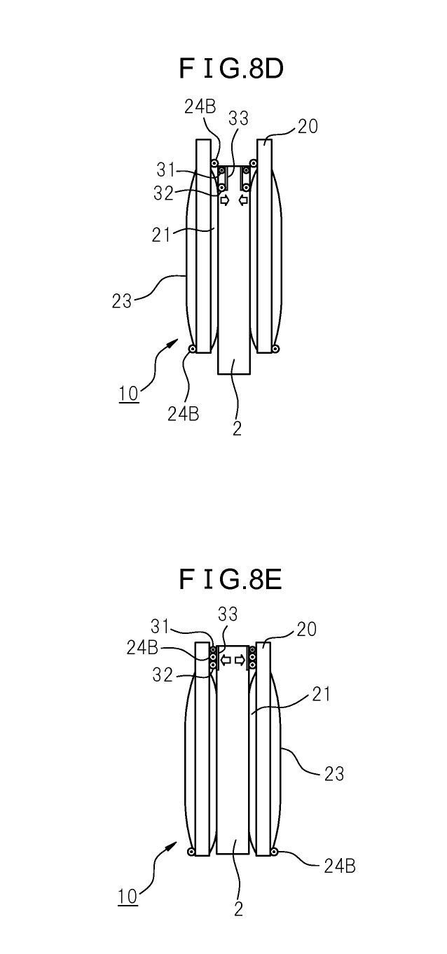

FIG. 8A to FIG. 8E explain in stages the operations of the different parts when a heat generating device constituted by a hard disk drive 2 is inserted into an above configured cooling system of multiple heat generating devices of the present application. FIG. 8A illustrates two cooling plates 10 and explains the case where a hard disk drive 2 is inserted between these two cooling plates 10. Note that, to facilitate understanding, illustration of the recessed parts of the front end part of the hard disk drive 2 will be omitted. Further, the roller parts 24B of the shaft are positioned at the front end parts of the frames 20.

If the hard disk drive 2 is placed positioned between the two cooling plates 10, first, the first rollers 31 of the shaft drive mechanisms 30 at the hard disk drive 2 abut against the roller parts 24B. The diameter of the roller parts 24B and the diameter of the second rollers 32 are the same, so the diameter of the first rollers 31 is smaller than the diameter of the roller parts 24B. Therefore, the first rollers 31 abut against the roller parts 24B at positions further from the frames 20 than the shafts of the roller parts 24B. For this reason, if the hard disk drive 2 is inserted between the cooling plates 10 from the state which is illustrated in FIG. 8A as illustrated in FIG. 8B, along with insertion of the hard disk drive 2, the first rollers 31 make the roller parts 24B move while rotating in directions by which the windup parts of the shafts wind up the pressing sheets 23. At this time, the above-mentioned sliders which support the shafts also move along the grooves and the first rollers 31 rotate in directions opposite to the directions of rotation of the roller parts 24B.

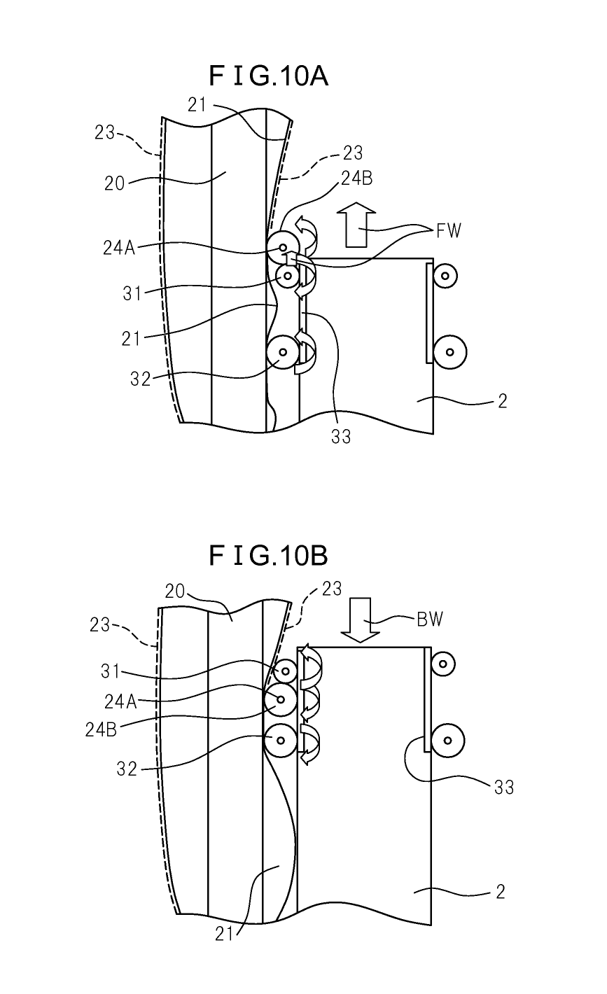

FIG. 10A illustrates the part X of FIG. 8B partially enlarged and explains the directions of rotation of the first and second rollers 31 and 32 and roller parts 24B when the hard disk drive 2 is pushed between the cooling plates 10. Note that, to facilitate understanding, FIG. 10A illustrate the directions of rotation of the first and second rollers 31 and 32 and the roller parts 24B at the left side of the hard disk drive 2, illustrates the outer skin of the flexible bag 21 by the solid lines, and illustrates the pressing sheet 23 by the broken lines. If the hard disk drive 2 moves in the arrow FW direction, the left side first roller 31 also moves in the arrow FW direction and rotates in the clockwise direction whereby the roller parts 24B are made to rotate in the counterclockwise direction.

Due to the counterclockwise rotation of the roller parts 24B, the pressing sheets 23 are wound up by the windup parts 24A of the shafts whereby the pressing sheets 23 press against the flexible bags 21 and make the inside cooling medium flow to the first roller 31 sides. At this time, the second rollers 32 contact the frames 20, so movement of the hard disk drive 2 in the arrow FW direction causes rotation in the counterclockwise direction.

If the hard disk drive 2 continues to be inserted between the cooling plates 10, finally the sliders which support the roller parts 24B reach the end parts of the grooves and can no longer move any further and movement of the roller parts 24B is stopped. This state is illustrated in FIG. 8C. The position of the roller parts 24B in the state of FIG. 8C is the position which is illustrated in the above-mentioned FIG. 6C. In this state, the hard disk drive 2 has a remaining margin enabling further insertion. If the hard disk drive 2 is further inserted between the cooling plates 10 from this state, as illustrated in FIG. 8D, the elevator plates 33 move to inside the recessed parts of the hard disk drive 2 and as a result the first rollers 31 ride over the roller parts 24B.

If the first rollers 31 finish riding over the roller parts 24B, the state becomes the one illustrated in FIG. 8E. The roller parts 24B are fit into the spaces between the first and second rollers 31 and 32, and the elevator plates 33 rise. The state which is illustrated in FIG. 8E is the state where the hard disk drive 2 has finished being inserted between the cooling plates 10. The elevator plates 33 are biased in the directions of the frames 20 due to the springs which are explained from FIG. 7A to FIG. 7C, so in this state, the hard disk drive 2 is positioned by the cooling plates 10. In the state of FIG. 8E, the flexible bags 21 closely contact the side surfaces of the hard disk drive 2. The heat which is generated at the hard disk drive 2 can be cooled by circulation of the cooling medium at the insides.

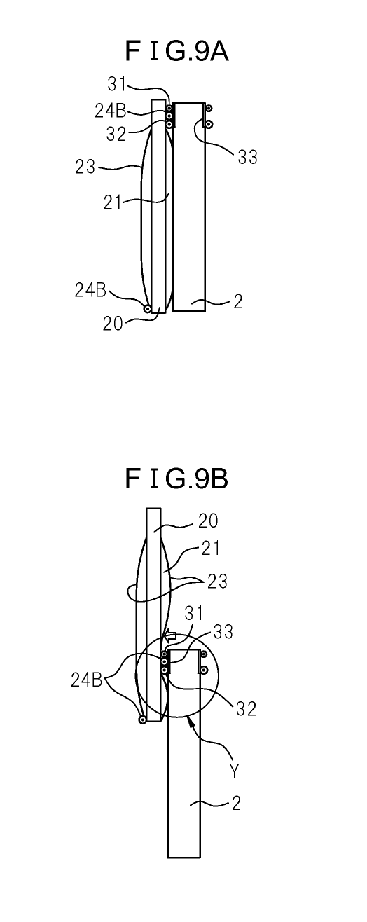

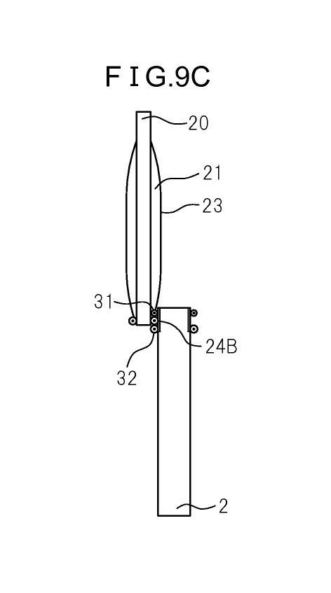

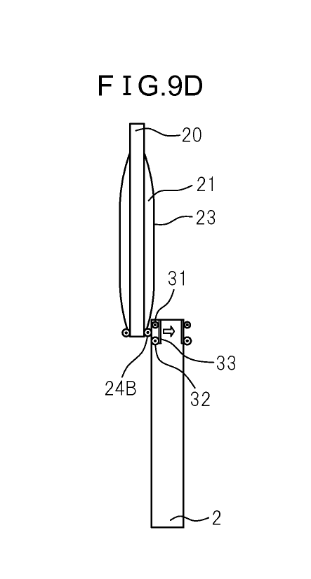

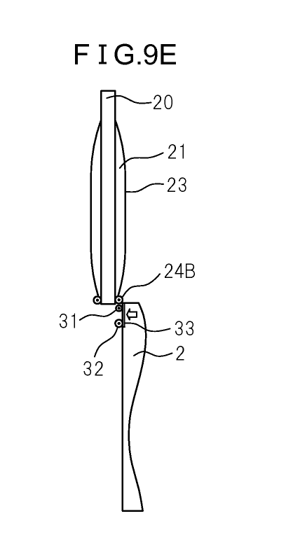

FIG. 9A to FIG. 9E explain in stages the operations of the parts when pulling out a hard disk drive 2 from the cooling system of multiple heat generating devices of the present application. FIG. 9A to FIG. 9E illustrate just a single cooling plate 10. Illustration of the cooling plate 10 at the opposite side is omitted.

If pulling out a hard disk drive 2 from the state of FIG. 9A, the first and second rollers 31 and 32, as illustrated in FIG. 9B, move together with the hard disk drive 2 while sandwiching the roller parts 24B. FIG. 10B illustrates the part Y of FIG. 9B partially enlarged. The rotational directions of the first and second rollers 31 and 32 and roller parts 24B when the hard disk drive 2 is pulled out from between the cooling plates 10 will be explained. In FIG. 10B as well, the outer skin of the flexible bag 21 is illustrated by the solid lines while the pressing sheet 23 is illustrated by the broken lines. If the hard disk drive 2 moves in the arrow BW direction, the second roller 32 rotates in the clockwise direction, the first roller 31 which moves together with the hard disk drive 2 contacts the roller parts 24B, and, due to the difference in diameters, the roller parts 24B are made to rotate in the clockwise direction. The first roller 31 itself contacts the roller parts 24B, so rotates in the counterclockwise direction.

By the roller parts 24B rotating in the clockwise direction, the pressing sheet 23 which is wound around the shaft is unwound. As a result, the cooling medium at the front side of the flexible bag 21 can be moved to the back side of the flexible bag 21. If the hard disk drive 2 continues to be pulled out from the cooling plates 10, finally the sliders which support the roller parts 24B reach the end parts of the grooves at the front side and no longer move any further, and the roller parts 24B stop moving. This state is illustrated in FIG. 9C. The position of the roller parts 24B in the state of FIG. 9C is the position which is illustrated in the above-mentioned FIG. 6A.

If the hard disk drive 2 is further pulled out from the cooling plates 10 in this state, as illustrated in FIG. 9D, the elevator plate 33 moves to the inside of the recessed part of the hard disk drive 2 and as a result the first roller 31 rides over the roller parts 24B. If the first roller 31 finishes riding over the roller parts 24B, the state becomes the one which is illustrated in FIG. 9E, the hard disk drive 2 is completely pulled out from the cooling plates 10, the elevator plate 33 rises, and the first and second rollers 31 and 32 return to the original positions.

As explained above, the cooling system of multiple heat generating devices of the present application enables active exchange with a large number of hard disk drives which are loaded in a large capacity storage apparatus. Note that, for the parts where hard disk drives are not yet loaded, dummies of the same shapes as the hard disk drives may be loaded. By employing the cooling systems of multiple heat generating devices of the present application, it was possible to reduce the noise in the large capacity storage apparatus by 3 dB and the consumed power of the blower fans by 15%.

Note that, the above explained cooling system of multiple heat generating devices is one example. The heat generating devices need not be hard disk drives. For example, the heat generating devices may also be blade type servers. Further, as the cooling medium, water or a coolant may be used.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A cooling system of multiple heat generating devices which can be inserted into and detached from an electronic apparatus, comprising
rigid body type frames which are provided at the electronic apparatus to be positioned at the two side surfaces of said heat generating devices,
flexible bag shaped members which are attached to the surfaces of said rigid body type frames which face side surfaces of said heat generating devices and inside of which a cooling medium circulates,
pressing sheets which have first ends which are fastened to the back end sides of said rigid body type frames, the side where said heat generating devices are inserted in said electronic apparatus being defined as the front sides, which have intermediate parts which cover said bag shaped members, which have other ends which are attached to shafts which can move over said rigid body type frames in the front-back direction, and which are wound around said shafts due to movement of said shafts, and
shaft drive mechanisms which are provided at front end parts of said heat generating devices and which makes said shafts rotate at the time of insertion or detachment of said heat generating devices.

2. The cooling system of multiple heat generating devices according to claim 1, wherein
each said shaft is provided with a windup part of said pressing sheet and roller parts which are provided with a larger diameter than said windup part and is driven by a shaft drive mechanism to rotate and move over said rigid body type frame, and
said shaft drive mechanism is provided inside a recessed part which is provided at said heat generating device and is formed provided with a first roller which abuts against said roller parts to make them rotate, a second roller which is provided separated from said first roller by a distance of at least the diameter of said roller parts and which has a larger diameter than said first roller, and an extension-retraction mechanism which makes said first and second rollers extend from and retract into said heat generating device.

3. The cooling system of multiple heat generating devices according to claim 2, wherein said extension-retraction mechanism is comprised of
an elevator plate to which shafts of said first and second rollers are attached and
a compression spring which is provided between said elevator plate and said recessed part.

4. The cooling system of multiple heat generating devices according to claim 2, wherein
the diameter of said second roller is equal to the diameter of said roller parts, and,
along with a heat generating device being inserted into said electronic apparatus, said first roller with a diameter smaller than said second roller is used to make said roller parts rotate and make said pressing sheet be wound up by said windup part while pressing against said bag shaped member.

5. The cooling system of multiple heat generating devices according to claim 4, wherein
grooves which extend in the front-back direction are formed at two end parts of each rigid body type frame in a direction vertical to the front-back direction,
said grooves have sliders inserted into them which slide along said grooves in the front-back direction,
two end parts of said shaft are supported at said sliders to be able to rotate, and
positions of back end parts of said grooves are positions at which a margin for further insertion of said heat generating device remains in the state where said sliders have been moved up to the back end parts of said grooves.

6. The cooling system of multiple heat generating devices according to claim 5, wherein a total length of each said heat generating device is a length by which insertion of said heat generating device in said electronic apparatus after said shaft has finished being moved results in said shaft drive mechanism sinking inside said recessed part and by which insertion into said electronic apparatus is completed when said first roller rides over said roller parts.

7. The cooling system of multiple heat generating devices according to claim 5, wherein,
along with a heat generating device being withdrawn from said electronic apparatus, said first roller is used to make said roller parts rotate and make said pressing sheet be unwound from said windup part while pressing against said bag shaped member, and
positions of front end parts of said grooves are positions at which said second roller of said shaft drive mechanism emerges at the outside of said electronic apparatus in the state where said sliders have been moved up to the front end parts of said grooves.

8. The cooling system of multiple heat generating devices according to claim 1, wherein,
inside said flexible bag shaped member, partition walls are provided which alternately stick out from the end parts in the front-back direction, and
said cooling medium circulates through the inside of said flexible bag shaped member along a snaking path which is formed by said partition walls.

9. The cooling system of multiple heat generating devices according to claim 8, wherein
an outlet part of said snaking path is connected by piping to one of a plurality of inlets of a first manifold,
an inlet part of said snaking path is connected by piping to one of a plurality of outlets of a second manifold,
between the outlet of said first manifold and the inlet of said second manifold, a heat exchanger which cools said cooling medium and a pump which makes said cooling medium move are provided.

10. The cooling system of multiple heat generating devices according to claim 9, wherein
said electronic apparatus is provided with loading parts of said heat generating devices which are provided with said rigid body type frames, control parts and power parts of said heat generating devices, and blower fans which are provided at the back side of said electronic apparatus and which suck in cooling air from the sides at the loading parts of said heat generating devices and discharge it to the back side,
said heat exchangers are provided in the vicinity of said blower fans.

11. The cooling system of multiple heat generating devices according to claim 10, wherein two systems of cooling paths which connect outlets and inlets of said first and second manifolds and are provided with said heat exchangers and said pumps are provided.

12. The cooling system of multiple heat generating devices according to claim 3, wherein
the diameter of said second roller is equal to the diameter of said roller parts, and,
along with a heat generating device being inserted into said electronic apparatus, said first roller with a diameter smaller than said second roller is used to make said roller parts rotate and make said pressing sheet be wound up by said windup part while pressing against said bag shaped member.

13. The cooling system of multiple heat generating devices according to claim 12, wherein
grooves which extend in the front-back direction are formed at two end parts of each rigid body type frame in a direction vertical to the front-back direction,
said grooves have sliders inserted into them which slide along said grooves in the front-back direction,
two end parts of said shaft are supported at said sliders to be able to rotate, and
positions of back end parts of said grooves are positions at which a margin for further insertion of said heat generating device remains in the state where said sliders have been moved up to the back end parts of said grooves.

14. The cooling system of multiple heat generating devices according to claim 13, wherein a total length of each said heat generating device is a length by which insertion of said heat generating device in said electronic apparatus after said shaft has finished being moved results in said shaft drive mechanism sinking inside said recessed part and by which insertion into said electronic apparatus is completed when said first roller rides over said roller parts.

15. The cooling system of multiple heat generating devices according to claim 14, wherein,
along with a heat generating device being withdrawn from said electronic apparatus, said first roller is used to make said roller parts rotate and make said pressing sheet be unwound from said windup part while pressing against said bag shaped member, and
positions of front end parts of said grooves are positions at which said second roller of said shaft drive mechanism emerges at the outside of said electronic apparatus in the state where said sliders have been moved up to the front end parts of said grooves.

16. The cooling system of multiple heat generating devices according to claim 15, wherein,
inside said flexible bag shaped member, partition walls are provided which alternately stick out from the end parts in the front-back direction, and
said cooling medium circulates through the inside of said flexible bag shaped member along a snaking path which is formed by said partition walls.

17. The cooling system of multiple heat generating devices according to claim 16, wherein
an outlet part of said snaking path is connected by piping to one of a plurality of inlets of a first manifold,
an inlet part of said snaking path is connected by piping to one of a plurality of outlets of a second manifold,
between the outlet of said first manifold and the inlet of said second manifold, a heat exchanger which cools said cooling medium and a pump which makes said cooling medium move are provided.

18. The cooling system of multiple heat generating devices according to claim 6, wherein,
along with a heat generating device being withdrawn from said electronic apparatus, said first roller is used to make said roller parts rotate and make said pressing sheet be unwound from said windup part while pressing against said bag shaped member, and
positions of front end parts of said grooves are positions at which said second roller of said shaft drive mechanism emerges at the outside of said electronic apparatus in the state where said sliders have been moved up to the front end parts of said grooves.

19. The cooling system of multiple heat generating devices according to claim 18, wherein,
inside said flexible bag shaped member, partition walls are provided which alternately stick out from the end parts in the front-back direction, and
said cooling medium circulates through the inside of said flexible bag shaped member along a snaking path which is formed by said partition walls.

20. The cooling system of multiple heat generating devices according to claim 7, wherein,
inside said flexible bag shaped member, partition walls are provided which alternately stick out from the end parts in the front-back direction, and
said cooling medium circulates through the inside of said flexible bag shaped member along a snaking path which is formed by said partition walls.
